(19) United States
(12) Patent Application Publication
(10) Pub. No.: US 2017/0294629 A1
(43) Pub. Date: Oct. 12, 2017

(54) LIGHT EMISSION FROM ELECTRICALLY BIASED GRAPHENE

(71) Applicant: THE TRUSTEES OF COLUMBIA UNIVERSITY IN THE CITY OF NEW YORK, NEW YORK, NY (US)

(72) Inventors: Young Duck Kim, New York, NY (US); Lei Wang, New York, NY (US); Sunwoo Lee, New York, NY (US); James Hone, New York, NY (US)

(73) Assignee: THE TRUSTEES OF COLUMBIA UNIVERSITY IN THE CITY OF NEW YORK, NEW YORK, NY (US)

(21) Appl. No.: 15/631,625

(22) Filed: Jun. 23, 2017

Related U.S. Application Data
(63) Continuation of application No. PCT/US2015/000208, filed on Dec. 23, 2015.
(60) Provisional application No. 62/129,526, filed on Mar. 6, 2015.
(60) Provisional application No. 62/127,576, filed on Mar. 3, 2015.
(60) Provisional application No. 62/096,643, filed on Dec. 24, 2014.

(51) Int. Cl. H01L 51/52; H01L 51/00

(52) U.S. Cl. CPC H01L 51/5296; H01L 51/0046

(57) ABSTRACT

Methods and systems for emitting light from electrically biased graphene are provided. An exemplary method of generating a light emission from graphene includes suspending a graphene membrane using at least one mechanical clamp and providing a current to the graphene membrane to establish a source-drain bias voltage along the graphene membrane.

### CROSS-REFERENCE TO RELATED APPLICATIONS

The present application is a continuation of International Application No. PCT/US15/000208, filed Dec. 23, 2015, which claims priority from United States Provisional Applications Nos. 62/096,643 filed Dec. 24, 2014, 62/127,576 filed Mar. 3, 2015, and 62/129,526 filed Mar. 6, 2015, the contents of which are hereby incorporated by reference herein in their entireties.

### NOTICE OF GOVERNMENT SUPPORT

This invention was made with government support under Contract Number FA9550-09-1-0705 awarded by the Air Force Office of Scientific Research and under Contract Number N00014-13-1-0662 awarded by the U.S. Office of Naval Research. The government has certain rights in the invention.

### BACKGROUND

Graphene is a two-dimensional (2D) carbon film one atom thick. Graphene can have certain useful properties such as charge carrier mobility, current capacity, thermal conductivity, mechanical stiffness and strength, optical transparency, high melting temperature (˜5000 K) and high-temperature stability.

Certain methods for wafer-scale graphene growth have been used in connection with electrodes and optoelectronic applications. For example, graphene-based photonic elements, where a number of graphene optoelectronic devices such as photodetector, optical modulators and plasmonic devices utilize graphene's strong light-matter interaction, can provide ultrafast carrier response over a broad spectral range.

In gapless graphene, radiative electron-hole recombination processes are not necessarily efficient at least in part due to the rapid energy relaxation that occurs through electron-electron and electron-phonon interactions. However, the above-noted properties of graphene can make it useful for thermal light emission. Thermal radiation from electrically biased graphene supported on a substrate can be limited to the infrared range, and can be inefficient as only a small fraction of the applied energy—about a part in one million—is converted into light radiation. Such limitations can be attributed to heat dissipation through the underlying substrate and a significant hot electron relaxation from extrinsic scattering effects such as charged impurities and surface polar optical phonon interaction, both of which can limit operating temperatures and brightness. Certain white light-emitting devices (LEDs) have shown limitations such as unstability at high temperature, energy loss by down conversion, toxicity of phosphorous and low-speed light modulation. Such white LED light modulation speed can be limited by the slow lifetime of phosphorus.

Thus, there remains a need for improved techniques for emitting light from graphene.

### SUMMARY

The disclosed subject matter provides methods and systems for emitting light from electrically biased graphene.

In certain embodiments, an exemplary method for generating a light emission from graphene includes suspending a graphene membrane using a circular mechanical clamp and providing a current to the graphene membrane to establish a source-drain bias voltage along the graphene membrane.

In certain embodiments, the graphene membrane can contain from about one to about ten layers of carbon atoms. The graphene membrane can have a width from about 0.5 μm to about 3 μm. The graphene membrane can be prepared by mechanical exfoliation or chemical vapor deposition (CVD). The source-drain bias voltage can be from about 1 V to about 4 V. The light emission can include photons having energy from about 0.1 eV to about 3 eV. In certain embodiments, the light emission can include photons having an energy from about 1.2 eV to about 3 eV.

In certain embodiments, the graphene membrane can be suspended over trench having a trench depth. The method can further include modulating the trench depth to alter the intensity of the light emission.

In certain embodiments, an exemplary method for generating a light emission from graphene includes encapsulating a graphene membrane using a dielectric material and providing a current to the graphene membrane to establish a source-drain bias voltage along the graphene membrane.

In certain embodiments, the dielectric material can include hexagonal boron nitride. The source-drain bias voltage can be from about 6 V to about 45 V.

In certain embodiments, an exemplary method for generating a light emission from hBN can include encapsulating a hBN layer using a graphene layer to from a hBN heterostructure and providing a current to the hBN structure to establish a source-drain bias voltage along the hBN heterostructure. In certain embodiments, the exemplary method further can include performing a direct tunneling injection.

In certain embodiments, the hBN heterostructure can include a hBN based encapsulating layer. The hBN layer can have an atomically thin tunneling barrier structure. The hBN heterostructure can include a color tunable structure and a color of the light emission can be tunable between a blue white color to an orange white color.

### BRIEF DESCRIPTION OF THE FIGURES

FIG. 1 depicts a method of generating a light emission from graphene according to one exemplary embodiment of the disclosed subject matter.

FIG. 2 depicts a method of generating a light emission from graphene according to another exemplary embodiment of the disclosed subject matter.

FIG. 3 depicts a system for generating a light emission from graphene according to one exemplary embodiment of the disclosed subject matter.

FIG. 4 depicts an alternative clamping arrangement for systems according to the disclosed subject matter.

FIG. 5 depicts a system for generating a light emission from graphene according to another exemplary embodiment of the disclosed subject matter.

FIG. 6 provides a schematic illustration of a process for fabricating suspended graphene membranes in a circular mechanical clamp.

FIG. 7 provides plots of (A) a current-voltage (I-V) curve; (B) simulated thermal conductivity; and (C) a temperature profile corresponding to electron temperature for monolayer graphene.

FIG. 8 depicts an example setup for measuring Raman spectra and light emissions for suspended graphene.

FIG. 9 depicts spectra of visible light emissions from (A) monolayer graphene and (B) tri-layer graphene at various source-drain bias voltages.

FIG. 10 provides a plot of intensity versus source-drain bias voltage for one example graphene membrane.

FIG. 11 provides a (A) Plot of simulated intensity as a function of trench depth and photon energy; and (B) a spectra of visible light emissions at various trench depths.

FIG. 12 provides current-voltage (I-V) curves and images of visible light emissions from encapsulated graphene membranes (A) in a vacuum and (B) under ambient conditions.

FIG. 13 depicts an example structure of a hBN heteostructure.

FIG. 14 depicts a (A) visible white light emission from a hBN heteostructure; and (B) spectrum of visible light emission from a hBN heteostructure.

FIG. 15 provides a plot of current intensity versus bias voltage for one example hBN heterostructure.

FIG. 16 provides a schematic illustration of radiation from electrically induced defect states.

FIG. 17 provides a (A) schematic illustration of an example graphene light emitter in accordance with one aspect of the disclosed subject matter, (B) a plot of current density as a function of applied electric field of example graphene light emitters, (C) an optical image of bright visible light emission from example microscale graphene light emitter under applied electric field, (D) uniform surface visible light emission from an example graphene/hBN heterostructure, (E) optical images showing exemplary radiation intensity increase by an applied electric field, and (F) a plot showing long-term stability of an example graphene light emitter under a vacuum condition.

FIG. 18 provides a (A) plot of radiation spectrum of an example graphene light emitter under vacuum with various electric fields and power, (B) radiation spectrum of a graphene light emitter under air and thermal radiation, and (C) a plot showing example radiation intensity as function of applied electric power (Pe) under vacuum and air.

FIG. 19 provides a (A) plot of current as function of applied electric field (F) with various example gate voltages (V_{BG}), (B) a plot of sheet conductance modulation by V_{BG} of an example graphene heterostructure with various F, (C) Raman spectroscopy of a graphene/hBN heterostructure for estimating lattice temperature (Tap), (D) Raman spectroscopy of an example monolayer graphene encapsulated by hBN layers, (E) a plot showing decoupling of electron and lattice temperature in example graphene light emitters, and (F) a plot of calculated Te profiles of an example graphene light emitter under various electric field.

FIG. 20 provides a (A) schematic of an example electrically driven ultrafast graphene light emitter, (B) a plot showing measured light signal from graphene, (C) a plot of time-resolved thermal radiation intensity (log scale) under various electrical pulse excitation, and (D) a plot of ultrafast light pulse generation from an example graphene light emitter under a 80 ps electrical pulse.

### DETAILED DESCRIPTION

The presently disclosed subject matter provides techniques for generating a light emission from graphene. In certain embodiments, the disclosed subject matter provides methods and systems for emitting light from a graphene membrane by providing a current to the graphene membrane.

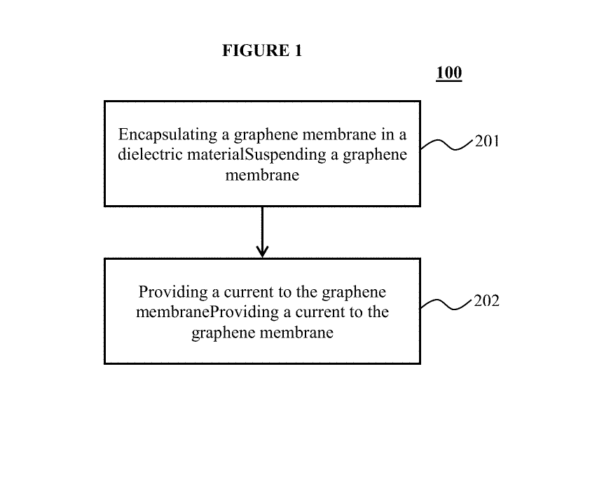

FIG. 1 is a schematic illustration of an exemplary method for generating a light emission. In certain embodiments, a method 100 includes suspending a graphene membrane 101. For example, the graphene membrane can be suspended using at least one mechanical clamp.

The method 100 can further include providing a current to the graphene membrane 102. In certain embodiments, electrical current can be introduced at one end of the graphene membrane, and a source-drain bias voltage can be established across the graphene membrane. For example, an electric field can be applied to the graphene membrane. The electric field can have a strength of about 0.01 V/μm to about 10 V/μm, e.g., from about 0.05 V/μm to about 5 V/μm, from about 0.1 V/μm to about 3 V/μm, or from about 0.2 V/μm to about 1 V/μm. In certain embodiment, the electric field has a strength from about 0.4 V/μm to about 0.5 V/μm.

As used herein, the term “about” or “approximately” means within an acceptable error range for the particular value as determined by one of ordinary skill in the art, which will depend in part on how the value is measured or determined, i.e., the limitations of the measurement system. For example, “about” can mean a range of up to 20%, up to 10%, up to 5%, and or up to 1% of a given value.

The source-drain bias voltage (V_{SD}) can be correlated to electric field strength (F). For example, the relationship can be represented by Formula 1, where L is the length of the graphene membrane.

F=V_{SD}L (1)

In certain embodiments, the source-drain bias voltage can be from about 0.1 V to about 10 V, from about 0.5 V to about 5 V or from about 1 V to about 4 V. In certain embodiments, the source-drain bias voltage can be repeatedly swept up and down, with the maximum voltage increasing each cycle until the desired source-drain bias voltage is established.

Additionally, providing a current can cause the graphene membrane to heat to temperatures greater than about 1200 K, e.g., greater than about 1400 K, greater than about 1600 K, greater than about 1800 K, or greater than about 2000 K. Under these conditions, the thermal conductivity of graphene can decrease. As a result of the decreased thermal conductivity, heat and electrons can pool at the center of the graphene membrane. The electrons can reach temperatures greater than about 2200 K, e.g., greater than about 2400 K, greater than about 2600 K, or greater than about 2800 K.

Umklapp phonon-phonon scattering can decrease the thermal conductivity of graphene at high temperatures (e.g., greater than about 1500 K). In a suspended graphene membrane, there is no heat dissipation to a substrate so the lattice temperature of the acoustic phonons (Tₐₚ) can be much higher compared to temperatures in a supported graphene membrane. As a result, the temperatures of optical phonons (Tₒₚ) and electrons (Tₑ) are also increased. Tₒₚ (which can be assumed to be equal to Tₑ because optical phonons and electrons are in equilibrium) is related to Tₐₚ as represented by Formula 2.

Tₒₚ=Tₐₚ+α(Tₐₚ−T₀) (2)

In Formula 2, a is a constant determined by the current and source-drain bias voltage and T₀ is the environmental temperature. Carrier mobility (μ) and thermal conductivity (κ) are inversely related to Tₑ and Tₐₚ, as shown in Formulas 3 and 4.

μ(Tₑ)=μ₀(T₀/Tₑ)^{β} (3)

κ(Tₐₚ)=κ₀(T₀/Tₐₚ)^{γ} (4)

As shown by Formulas 2-4, carrier mobility and thermal conductivity will decrease as Tₐₚ increases. Therefore, carrier mobility and thermal conductivity are reduced when the graphene membrane is suspended and heat dissipation is reduced, compared to when the graphene membrane is supported on a substrate.

Under these conditions, the graphene membrane can emit photons. Because the hot electrons are centralized in the graphene membrane, the emitted photons can be localized at a point in the center of the graphene membrane. The photons can have an energy from about 0.1 eV to about 3 eV, i.e., can emit light on the infrared or visible spectrum. In certain embodiments, the photons can have an energy from about 1.2 eV to about 3 eV, i.e., can emit light on the visible spectrum.

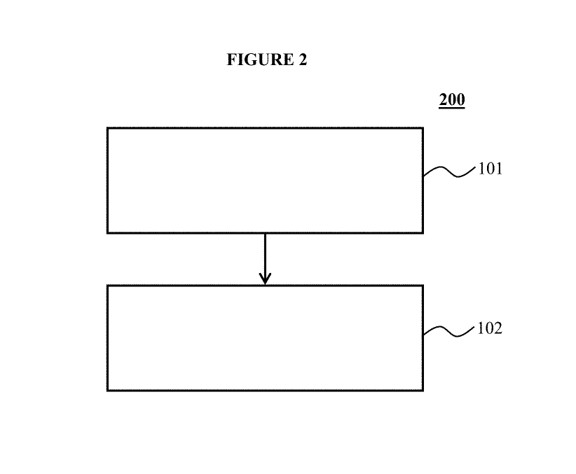

FIG. 2 is a schematic illustration of another exemplary method for generating a light emission. The method 200 can include encapsulating a graphene membrane in a dielectric material 201. For example, the dielectric material can be hexagonal boron nitride.

The method 200 can further include providing a current to the graphene membrane 202. In certain embodiments, electrical current can be introduced at one end of the graphene membrane, and a source-drain bias voltage can be established across the graphene membrane. The source-drain bias voltage can be from about 1 V to about 50 V, e.g., from about 6 V to about 45 V.

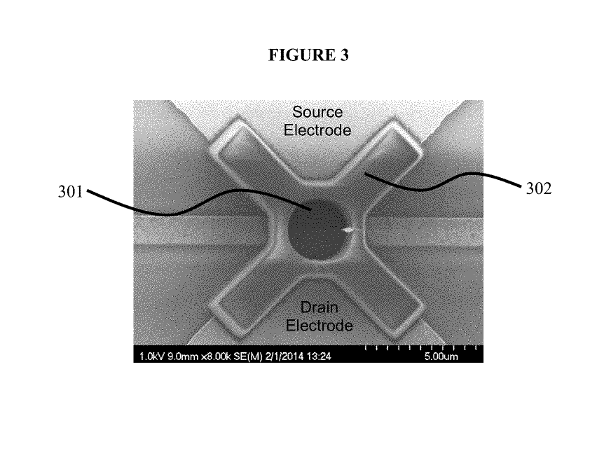

FIG. 3 provides a schematic illustration of an exemplary system for generating a light emission. In certain embodiments, a system 300 includes a graphene membrane 301 and mechanical clamp 302.

The graphene membrane can have a certain number of layers of carbon atoms. For example, the graphene membrane can have from about 1 to about 100 layers. In certain embodiments, the graphene membrane can be monolayer, i.e., a single layer of carbon atoms. In other certain embodiments, the graphene membrane can have from about 2 to about 10 layers.

In certain embodiments, the graphene membrane can have a width from about 0.5 μm to about 15 μm, e.g., from about 1 μm to about 10 μm, or from about 2 μm to about 7 μm. The graphene membrane can have a length from about 1 μm to about 40 μm, e.g., from about 2 μm to about 30 μm, or from about 3 μm to about 20 μm.

In certain embodiments, the graphene membrane can be prepared by mechanical exfoliation. Alternatively, the graphene membrane can be prepared by chemical vapor deposition (CVD). Alternatively, the graphene membrane can be prepared by physical vapor deposition (PVD).

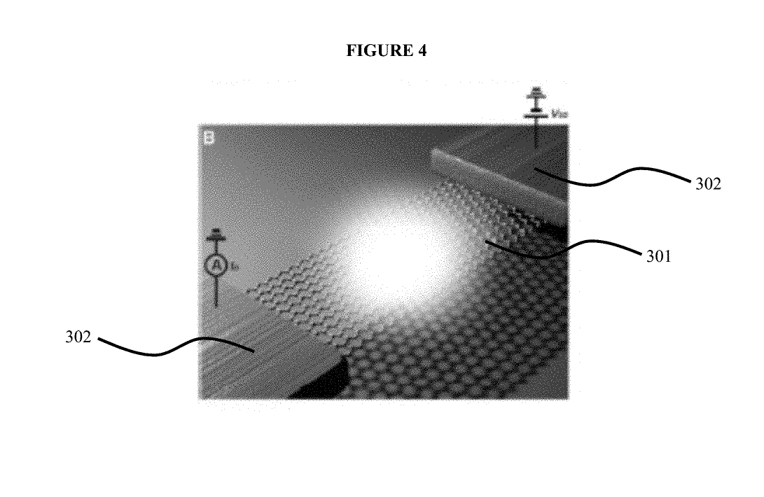

The graphene membrane can be suspended using one or more mechanical clamps. For example, the graphene membrane can be suspended within a circular or elliptical mechanical clamp (see FIG. 3). A circular or elliptical mechanical clamp can provide a geometry that increases the mechanical stability of the graphene by enforcing structural rigidity onto the graphene membrane. Additionally, a circular or elliptical mechanical clamp can provide a bypass for the current at high strength electric fields. In certain embodiments, a circular mechanical clamp can have a diameter of about 2 μm. An elliptical mechanical clamp can have a length of about 4 μm and a width of about 2.5 μm. In alternative embodiments, the graphene membrane can be suspended between two mechanical clamps, where each clamp holds an opposite end of the graphene membrane (see FIG. 4).

In certain embodiments, the mechanical clamp can be made of a polymeric or dielectric material. In particular embodiments, the mechanical clamp is made using SU-8 photoresist. Alternatively, the mechanical clamp can be made of a semiconducting or metallic material. The clamp(s) can include one or more electrodes. By way of example, the electrodes can be made of a conductive material, such as gold (Au), silver (Ag), copper (Cu), or chromium (Cr).

In certain embodiments, the graphene membrane can be suspended over a substrate. For example, the graphene membrane can be suspended over a trench within a substrate. For example, the substrate can be a material having electrical properties, e.g., silicon or silicon dioxide. The trench can have a depth from about 80 nm to about 1200 nm.

In certain embodiments, the trench depth can affect the spectrum of the light emitted from the graphene. For example, light can be reflected from the substrate and create constructive or destructive interference with the light emitted from the graphene membrane. As an example, the destructive interference can be approximated by Formula 5, where D represents the trench depth.

Δ(D)=(1242.4 nm/2D)eV (5)

Using Formula 5, radiation having a particular wavelength can be selectively enhanced by altering the trench depth of the substrate. For example, radiation intensity can be increased by up to about 100% by using constructive interference. Alternatively or additionally, radiation intensity can be decreased by up to about 40% by using destructive interference. Selectively enhancing radiation has potential utility in the field of optoelectronics.

In certain embodiments, the intensity of thermal radiation from graphene in a given angle θ can be calculated using Formula 6 (generalized Kirchoff's law).

I_{ω,a}(ω,θ,Tₑ)=a_{ω,a}(ω,θ,Tₑ)I_{ω,b}(ω,Tₑ) (6)

In Formula 6, a_{ω,a}(ω, θ, Tₑ) is a spectral directional absorptivity (emissivity) of the graphene layer in the stack for a given polarization of electromagnetic wave α=TE, TM. ω is frequency. I_{ω, b}(ω, Tₑ)=ω²Θ(ω, Tₑ)/8π³c² is the intensity of black-body radiation for a single polarization, Θ(ω)=ω/(exp (ω/k_{B}Tₑ)−1). is the reduced Planck's constant, k_{B} is Boltzmann's constant, and Tₑ is the electron temperature, which is used a fitting parameter. The absorptivity (emissivity) of the graphene can be calculated by solving analytically Maxwell's equations for a plane wave incident on the hBN/graphene/hBN.

In certain embodiments, two or more suspended graphene membranes can be arranged in an array, such that the graphene membranes are independently programmable.

A person having ordinary skill in the art will recognize that alternative arrangements of graphene membranes can be used to achieve this result. For example, graphene membranes can be encapsulated in a dielectric material. In certain embodiments, the graphene membrane can be encapsulated in hexagonal boron nitride (hBN). For example, the graphene membrane can be encapsulated with 2D or 3D hBN.

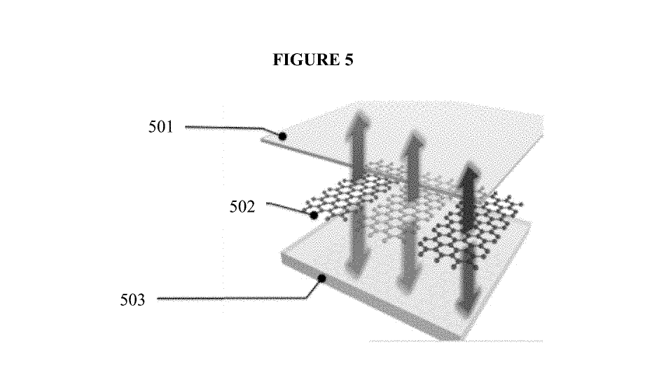

It should be noted that encapsulated graphene membranes can emit light under ambient conditions, unlike suspended graphene membranes which is often operated below a burn temperature or in a vacuum or inert gas. Encapsulation can allow the graphene membranes to emit light under ambient conditions, and at temperatures as high as 3000 K. For the purpose of illustration, FIG. 5 provides a schematic illustration of an exemplary system for generating a light emission from an 2D encapsulated graphene membrane. The graphene membrane 502 can be sandwiched between two layers, e.g., an encapsulation layer 501 and a substrate 503. This structure can provide a seal to prevent the graphene membrane from burning at high temperatures. Additionally, the encapsulation layers can provide a path for heat, to allow fast cooling of the graphene membrane. Because encapsulated graphene membranes can emit light under ambient conditions and are thin and transparent, they can be integrated with a photonic circuit or other optical component, such as an optical cavity, photonic crystal, or flexible and transparent substrate.

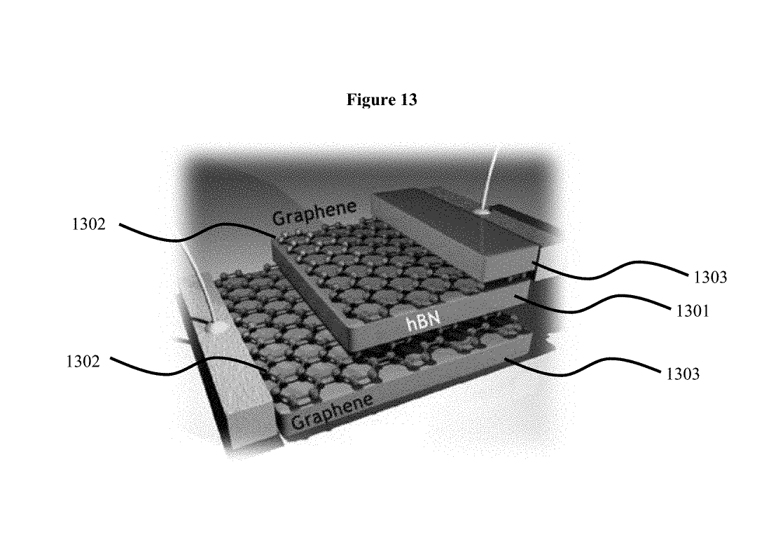

In certain embodiments, the disclosed system can include a hBN based light emitter 1300. As shown in FIG. 13, the hBN based light emitter 1300 can include graphene/hBN/graphene vertical tunneling structures. The hBN layer 1301 can be an atomically thin, flexible, and transparent tunneling barrier structure. The graphene 1302 can include a highly transparent electrode and tunable workfunction for efficient electron hole injection. In some embodiments, the light-emitter 1300 can include hBN an encapsulation layer 1303 for realization of high stable practical encapsulation devices with high level of performance. For example, the light-emitter can include a hBN/graphene/hBN/graphene/hBN structure. The light-emitter with hBN encapsulation layers 1303 can minimize extrinsic scattering effects such as charged impurities and surface polar optical phonon interaction.

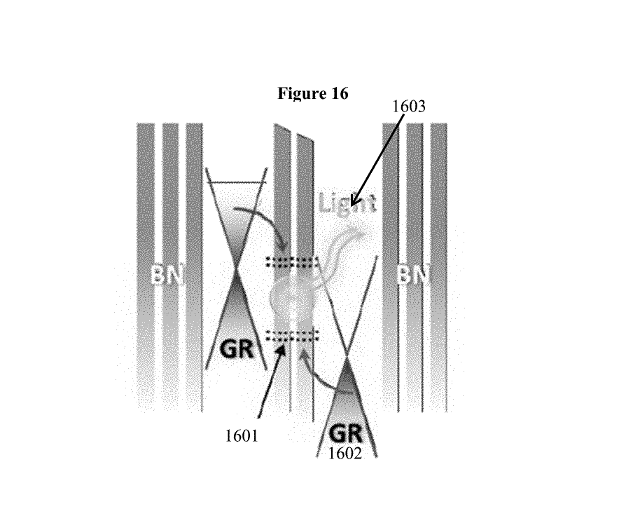

FIG. 16 provides a schematic illustration of an exemplary electrically tunable white light emission from hBN. The white light emission 1603 can be attributed to the electrostatic bias induced deep level defect states 1601 in the band gap of hBN and direct filling of electron hole from graphene electrodes 1602 by tunneling. The white light emission from hBN by direct tunneling carrier injection can induce the high speed of light modulation above GHz and reduce the energy loss by down-conversion layers. In some embodiments, as the applied bias increases, transition from the direct tunneling to the Fowler-Nordheim tunneling can occur.

In some embodiments, the disclosed system can induce the tunable of white light emission for cool and warm white color by applied bias direction. For example, the disclosed system can have asymmetric electron-hole recombination in the hBN layer by applying bias, which induce the tunable color temperature from 2000 K (Orange white) to 4000 K (Blue white). The tunable white light emission from the disclosed system can affect the physiological, human circadian balance and health care.

In some embodiments, the disclosed system can include a photonic waveguide for information processing and an optical cavity structure such as photonic crystal or/and hyperbolic metamaterials to extract photon emission. The optical cavity can increase emission efficiency.

In some embodiments, the disclosed system can include an electrically driven single photon source based on the single defect states in the hBN hetero structure, which can operate at room temperature for quantum information processing.

In some embodiments, all of the materials can be chemically inert and be biocompatibe. The hBN hetetostructure can have high-temperature stability, high thermal conductivity, and have high performance under high current density. The disclosed system can be utilized for various applications as a heath care lighting, ultrafast light source for optical communications, deep UV light source, broadband (Deep UV to near IR) photodetector, biomedical light source for optogenetics, and Nanoscale medical sterilization source.

The methods and systems of the presently disclosed subject matter can provide advantages over certain existing technologies, including decreased heat dissipation, and thus efficient conversion of electrical energy to light radiation. For example, compared to certain prior technologies, there is decreased heat dissipation between suspended graphene and a substrate. Additionally, the decreased thermal conductivity at high temperatures reduces the amount of heat dissipation within the graphene membrane. This increased conversion of electrical energy can result in light emissions on the visible spectrum. An additional advantage includes mechanical and thermal stability of the graphene membrane over repeated light emissions.

In some embodiments, the disclosed system can include electrically driven ultrafast thermal light emitters. The optical phonon energy of hBN can lead to increased currents under certain bias, allowing electron temperatures up to 2,000 K to achieve emission across a broad spectrum ranging from the visible to the near-infrared. For example, the 10-20 nm thick hBN layers can provide improved encapsulation, permitting stable operation under ambient conditions, and strongly modify the emission spectrum, e.g., by providing up to 460% enhancement for a broad peak centered at 718 nm by engineering confined local optical density of states.

In some embodiments, the disclosed system can have a light pulse generation up to 10 GHz bandwidth for on-chip photonic circuits. The disclosed system can induce decoupling of the electronic and lattice temperatures due to weak electron-acoustic phonon coupling. The decoupling, combined with ultrafast charge carrier dynamics in graphene, can induce fast electrical modulation of the light output. Electrons and optical phonons can be thermalized in graphene/hBN heterostructures under high bias (e.g., up to ˜50V), but out of equilibrium with acoustic phonons, even in steady state, for efficient and ultrafast light generation.

### Examples

The presently disclosed subject matter will be better understood by reference to the following Examples. These Examples are provided as merely illustrative of the disclosed methods and systems, and should be considered as a limitation in any way.

### Example 1: Preparing Suspended Graphene Membranes Using Mechanically Exfoliated Graphene

This Example describes one exemplary method of making an atomically thin suspended graphene membranes with mechanically exfoliated graphene.

Kish graphene was transferred onto an SiO₂/Si substrate. PMMA (polymethyl methacrylate, 950 K, C4) was spin-coated onto the graphene at 4500 rpm, followed by a baking process at 180° C. for 5 minutes. The PMMA was formed into an etch mask by exposing PMMA on unwanted areas of graphene using electron beam lithography. The graphene was patterned by O₂ etching using the PMMA mask. The PMMA was removed using acetone to reveal the patterned graphene array including multiple graphene membranes.

To attach the graphene membranes to the mechanical clamps, PMMA was again spin-coated onto the graphene membranes using the same procedure. The PMMA with graphene was separated from the SiO₂/Si substrate in 10 wt-% potassium hydroxide (KOH) solution. The PMMA with graphene was rinsed with water and dried at room temperature under nitrogen. The graphene was aligned onto a substrate having pre-formed trenches (with depths from 300 to 1000 nm) and each end of the graphene membrane was adhered to gold (Au) electrodes on the substrate. The PMMA was removed by an acetone wash and isopropanol rinse. The suspended graphene membranes were dried in a critical point drying process.

### Example 2: Preparing Suspended Graphene Membranes Using Chemical Vapor Deposition (CVD) Graphene

This Example describes an exemplary method of making an atomically thin suspended graphene membranes with chemical vapor deposition (CVD) graphene.

CVD graphene was transferred onto an SiO₂/Si substrate and patterned as described in Example 1. Electrodes were patterned by electron beam lithography and metals (Cr/Au at 20/80 nm) were deposited onto the electrodes. SiO₂ was removed from the graphene using buffered oxide etchants (BOE) or hydrofluoric acid (HF) and rinsed with D.I. water. The suspended graphene membranes were dried in a critical point drying process.

### Example 3: Preparing Graphene Membranes with Circular Mechanical Clamps

This Example describes one method of fabricating clamped graphene membranes using a circular mechanical clamp.

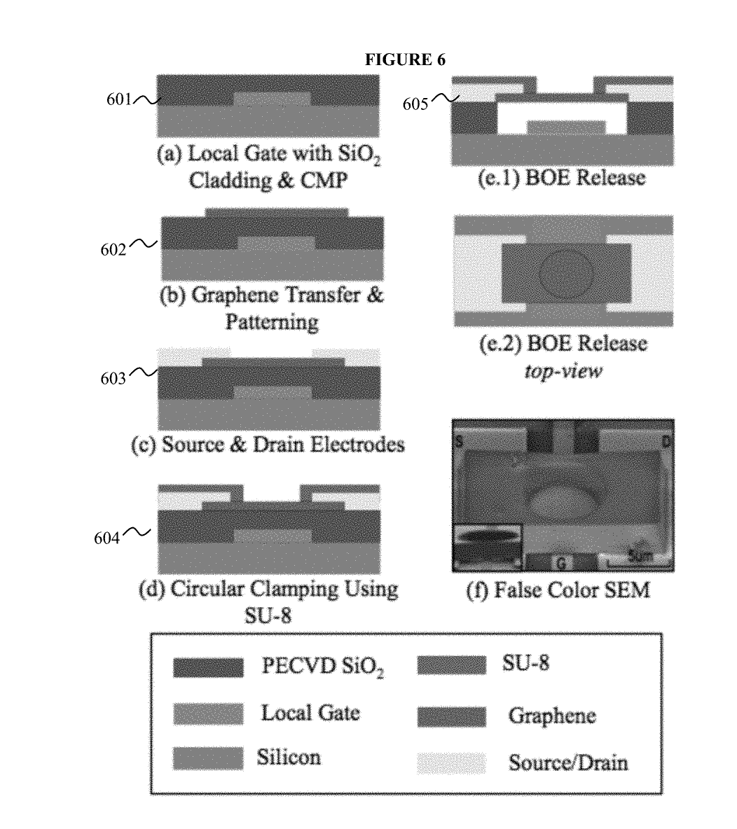

FIG. 6 depicts a flow chart showing one exemplary method of fabricating circularly-clamped graphene membranes. A local gate can be layered onto a silicon substrate and coated with SiO₂ using plasma-enhanced chemical vapor deposition (PECVD) 601. Graphene can be transferred onto a top surface and patterned 602, e.g., using the methods described in Examples 1 and 2. Electrodes can be applied to either end of the graphene 603. The top surface of the electrodes can be coated with SU-8 photoresist 604. Then, buffered oxide etchants (BOE) can be used to remove some of the SiO₂, to reveal a suspended graphene membrane 605. Using this method, the SU-8 photoresist can form a circular clamp to provide mechanical support for the graphene membrane.

### Example 4: Thermal Simulation of Monolayer and Tri-Layer Graphene Membranes

Thermal conductivity and photon energy can depend on the number of layers in a suspended graphene membrane. Additionally, as discussed with reference to Formulas 2-4, thermal conductivity can decrease as the lattice temperature increases.

In the case of monolayer graphene, and with reference to Formula 3, the minimum carrier mobility (μ) can be taken as 10000 cm²V⁻¹s⁻¹ and β can be 1.7. With reference to Formula 4, thermal conductivity (κ₀) can be taken as 2700 Wm⁻¹K⁻¹ and γ can be 1.92. Additionally, it is assumed that T₀ is 300 K. Using these assumptions, the source-drain bias voltage (V_{SD}) for different simulations of monolayer graphene membranes can be calculated, as shown in Table 1.

TABLE 1
Source-drain bias voltage in suspended monolayer
graphene membranes.

| V_{SD} | μ | Width | Tₒₚ | Tₐₚ |
|---|---|---|---|---|
| (V) | (cm²V⁻¹s⁻¹) | (μm) | (K) | (K) |
| 2.7 | 10000, 10250 | 0.784, 0.765 | 2634, 3039 | 1979, 2270 |
| 2.6 | 10000, 11500 | 0.796, 0.705 | 1802, 3016 | 1380, 2254 |
| 2.5 | 10000, 12700 | 0.87, 0.705 | 1381, 2951 | 1077, 2200 |
| 2.3 | 10000, 12700 | 1.15, 0.92 | 975, 1474 | 785, 1144 |
| 2.0 | 10000, 12700 | 1.63, 1.28 | 665, 838 | 562, 687 |
| 1.6 | 10000, 12700 | 1.93, 1.52 | 471, 525 | 423, 462 |

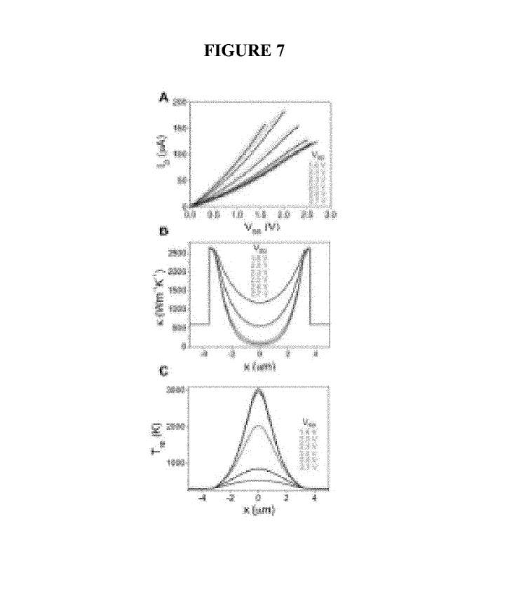

Furthermore, FIG. 7A provides the current (I_{D})-voltage (V_{SD}) curve for monolayer graphene. FIG. 7B simulates the thermal conductivity of monolayer graphene based on the current-voltage curve and Formulas 3 and 4. FIG. 7C provides a temperature profile of the optical phonon temperature (which is assumed to be equal to the electron temperature) of monolayer graphene across the length of the graphene membrane, and for various source-drain bias voltages. As shown in FIGS. 7B and 7C, where the temperature is greatest (i.e., at the center of the graphene membrane), the thermal conductivity is lowest.

In the case of tri-layer graphene, and with reference to Formula 3, the minimum carrier mobility (μ) can be taken as 2200 cm²V⁻¹s⁻¹ and β can be 1.155. With reference to Formula 4, thermal conductivity (κ₀) can be taken as 1900 Wm⁻¹K⁻¹ and γ can be 1. Additionally, it is assumed that T₀ is 300 K. Using these assumptions, the source-drain bias voltage (V_{SD}) for different simulations of tri-layer graphene membranes can be calculated, as shown in Table 2.

TABLE 2
Source-drain bias voltage in suspended tri-layer
graphene membranes.

| V_{SD} | μ | Width | Tₒₚ | Tₐₚ |
|---|---|---|---|---|
| (V) | (cm²V⁻¹s⁻¹) | (μm) | (K) | (K) |
| 3.65 | 2220, 2500 | 1.73, 1.63 | 2425, 2866 | 1934, 2275 |
| 3.6 | 2220, 2500 | 1.78, 1.67 | 2284, 2741 | 1826, 2177 |
| 3.55 | 2220, 2500 | 1.82, 1.71 | 2240, 2650 | 1792, 2106 |
| 3.5 | 2220, 2500 | 1.89, 1.78 | 2157, 2508 | 1729, 1999 |
| 3.45 | 2220, 2500 | 2.02, 1.89 | 2017, 2412 | 1620, 1924 |
| 3.4 | 2220, 2500 | 2.17, 2.05 | 1989, 2333 | 1600, 1865 |
| 3.35 | 2220, 2500 | 2.62, 2.46 | 1902, 2212 | 1533, 1771 |
| 3.3 | 2220, 2500 | 2.8, 2.64 | 1852, 2124 | 1494, 1704 |
| 3.25 | 2220, 2500 | 2.9, 2.72 | 1744, 2049 | 1410, 1645 |
| 3 | 2220, 2500 | 3, 2.82 | 1447, 1645 | 1182, 1334 |

These data show simulate maximum and minimum widths and thermal conductivities for monolayer and tri-layer suspended graphene membranes across multiple source-drain bias voltages.

### Example 5: Measuring Intensity of Emitted Light

In this Example, the intensity of light emitted from suspended graphene is observed and measured.

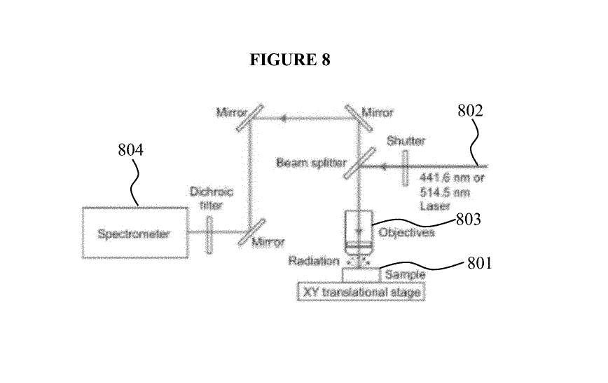

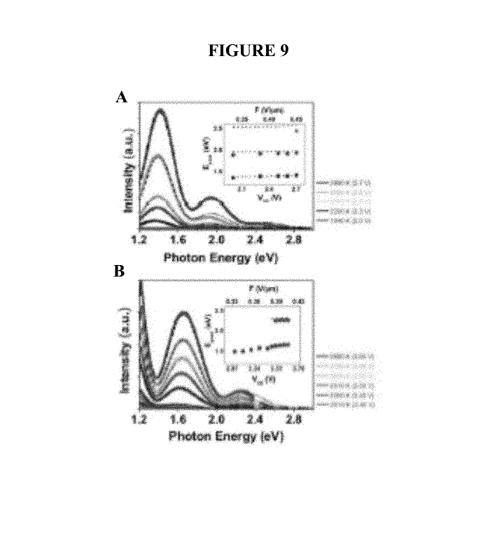

FIG. 8 provides one example setup for measuring Raman spectra and light emissions from a graphene sample 801. Both the Raman spectra and light emissions can be measured using the a laser 802, e.g., the 514.5 nm line of an Ar ion laser or the 441.6 nm line of a He—Cd laser with a power of 500 μW. The laser beam can be focused on the sample, e.g., using an objective lens 803 (e.g., 50×, NA 0.42, WD 20.3 mm). A spectrometer 804 (e.g., Jobin-Yvon Triax 320, 1200 groove/mm) and charge-coupled device array (e.g., Andor iDus DU420A BR-DD) can be used to record the spectra. FIGS. 9A-B provide spectra of visible light emissions from (A) monolayer graphene and (B) tri-layer graphene at various source-drain bias voltages.

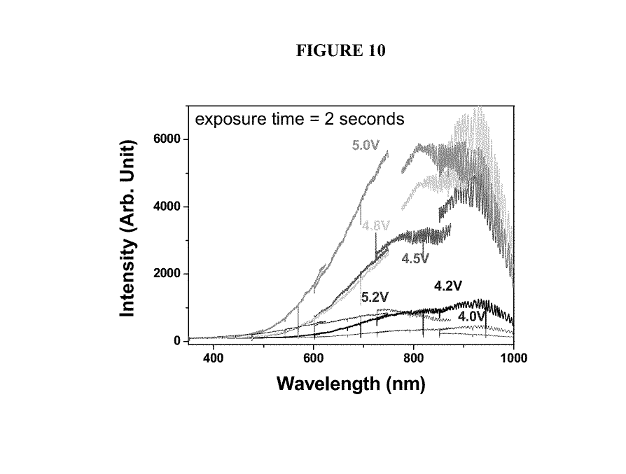

Additionally, the intensity can be plotted against the source-drain bias voltage to determine a critical voltage for maximum intensity. In one particular example, as shown in FIG. 10, as the source-drain bias voltage increased, so did the intensity, until a critical voltage of 5 V. Additionally, it was observed that the emitted light was wavelength-selective, i.e., had zero intensity at certain wavelengths on the visible light spectrum.

### Example 6: Modulating Trench Depth on the Substrate

This Example illustrates modulating trench depth, where the graphene membrane is suspended over a substrate containing trenches.

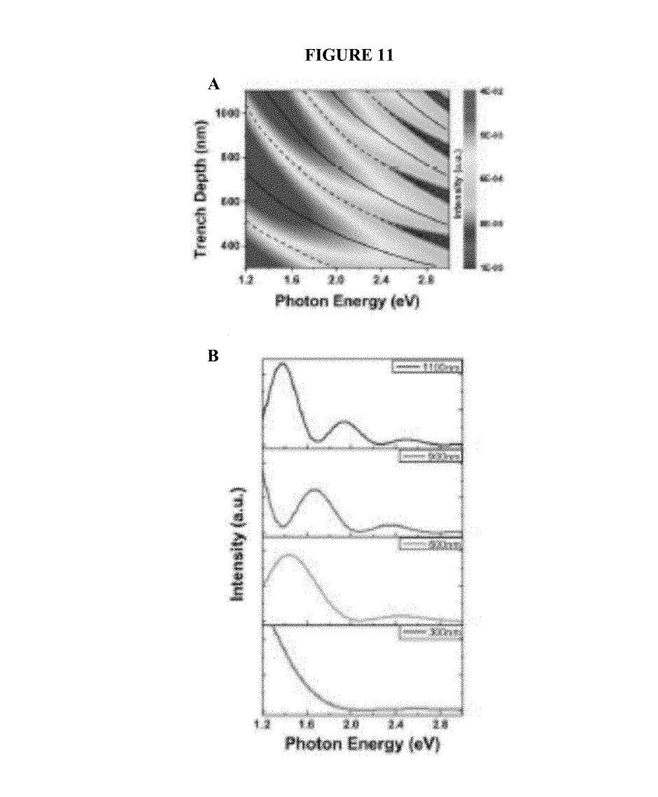

With reference to Formula 5, trench depth can be modulated to alter the intensity of radiation reflected off the substrate. In FIG. 11A, the simulated intensity of radiation is presented as a function of trench depth and photon energy. The electron temperature is assumed to be constant at 2850 K. In FIG. 11A, the solid lines show constructive interference and the dashed lines show destructive interference. FIG. 11B shows the spectra of the emitted light at various trench depths. Depending on the trench depth, the intensity of the light is highest at different photon energies (i.e., different wavelengths). These data illustrate how trench depth can be used to modulate the intensity of the emitted light from graphene.

### Example 7: Visible Light Emissions from Encapsulated Graphene Under Ambient Conditions

This Example demonstrates visible light emissions from graphene encapsulated in hexagonal boron nitride (hBN) under ambient conditions.

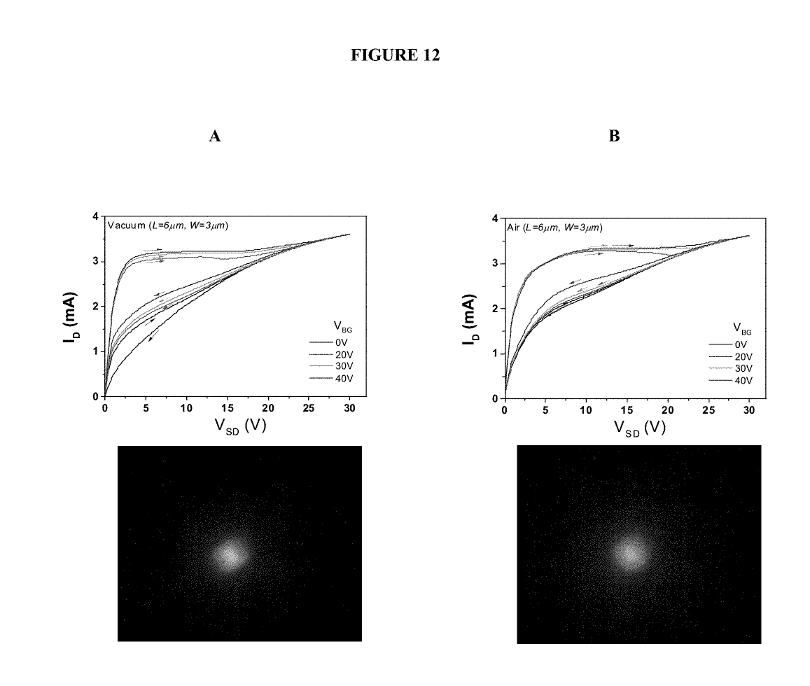

A current was applied to a graphene membrane encapsulated in hBN within a vacuum. At a source-drain bias voltage of 46 V, a visible light emission was observed. FIG. 12A shows an image of the visible light emission and the current-voltage curve for the encapsulated graphene membrane in a vacuum.

Under ambient conditions, a current was also applied to a second graphene membrane encapsulated in hBN. At a source-drain bias voltage of 30 V, a visible light emission was observed. FIG. 12B shows an image of the visible light emission and the current-voltage curve for the encapsulated graphene membrane under ambient conditions.

These data show that an encapsulated graphene membrane can emit visible light under ambient conditions.

### Example 8: Electrically Tunable White Light Emission in Atomically Thin Hexagonal Nitride

In this example, a hBN based white light-emitter was fabricated and a white-light emission was observed and measured.

Optoelectronic 2D materials can have potential benefits as emitters for disinfection, spectroscopy, and fluorescence analysis. They can be a low power calibration source for astrophysics. Especially, hexagonal boron nitride (hBN), a wide-bandgap III-V material, can be a material for absorption/emission in the deep ultraviolet region.

FIG. 13 provides one exemplary system of the white light-emitter 1300 with graphene/hBN/graphene vertical tunneling structures. The hBN 1301 and graphene layers 1302 were co-laminated using ultraclean van der Waals transfer techniques. The hBN layer 1301 can be atomically thin tunneling barrier and the graphene layer can comprises highly transparent and large tunable of workfunction electrodes for efficient electron hole injections. The graphene electrodes can have independent one-dimensional edge contacts to each graphene layers for low contact resistance without alignment challenge. In some embodiments, the graphene electrodes can include highly doped graphene electrodes using chemical and plasma treatments for efficient electron and hole injection to hBN.

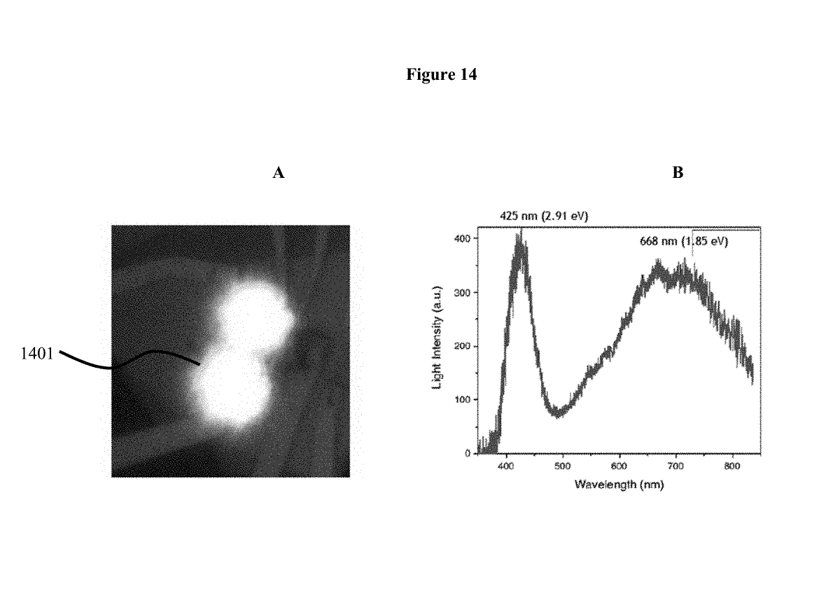

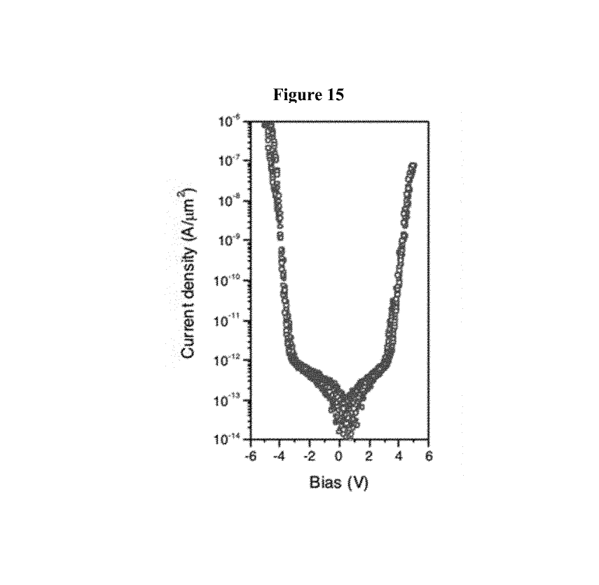

The white light-emission from the hBN heterostructure was detected under high bias tunneling regime above ˜1V/nm electric field between top and bottom graphene electrode. As shown in FIG. 14A, white light emissions 1404 were initiated from the edge of the overlap area of two graphene layers. FIG. 15 provides that as applied bias increased, the increased current density and the surface emission from entire overlap area were detected. FIG. 14B illustrates that two main emission peaks at 425 nm and 668 nm were detected from radiation spectrum of the hBN light emitter. The detected spectrum of the hBN light emitter was similar to spectrum of commercial white LED, having blue GaN LED with phosphorus. The light emitted from the hBN structure can be brighter than the commercial white LED. The light direct and ultrafast carrier injection through tunneling can improve the efficiency for white lighting of the disclosed system without any down converse element and fast light modulation.

In some embodiments, the disclosed system can be utilized for tunneling measurements under high electric field without a breakdown of dielectrics such as SiO2 and Al2O3.

### Example 9: Preparing hBN/Graphene/hBN Heterostructures

This Example describes an example method of fabricating hBN/graphene/hBN heterostructures.

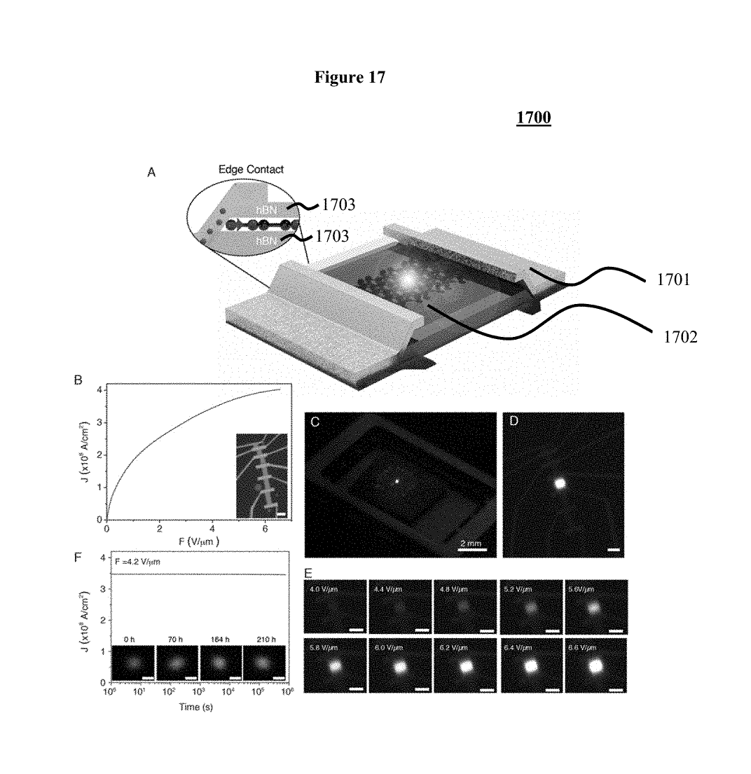

To fabricate the graphene light emitters, hBN/graphene/hBN heterostructures 1701 were first assembled by the well-known van der Waals dry pick-up method using exfoliated monolayer graphene and exfoliated hBN flakes with 10-20 nm thickness and transferred to a SiO₂ (285 nm)/Si substrate, as shown in FIG. 17A. FIG. 17A provides a schematic illustration of an exemplary system for generating a light emission. In certain embodiments, a system 1700 includes a graphene membrane 1702 and mechanical clamp 1801. The graphene membrane 1702 can be sandwiched between two layers, e.g., hBN encapsulation layers 1703.

Electrical contacts were formed by etching the assembled heterostructure and depositing metal (Cr/Pd/Au) to the exposed edge. The realized graphene heterostructure exhibits mobility near the intrinsic acoustic phonon scattering limit at room temperature). The atomically clean interface eliminates extrinsic effects such as surface roughness, defects and charged impurities, which allows the investigation of intrinsic electro-thermal properties e.g. thermal radiation, energy dissipation and ultrafast dynamics of hot electrons (e.g., up to 2800K) under high electric field (e.g., up to ˜6.6 V/μm).

The encapsulated graphene devices show stable and robust electrical transport under high electric fields (F) up to ˜6.6 V/μm with high current density (J) up to ˜4.0×10⁸ A/cm², as shown in FIG. 17B. At high current density, bright visible light emission was observed from these micron-scale structures as shown in FIG. 17C. The visible light emission is seen across the channel region and increases in intensity with applied electric field as shown in FIGS. 17D and 17E.

To test stability of the disclosed system, the long-term performance of the graphene light emitter under high electric field (F=4.2 V/μm) and high current density (J˜3.4×10(A/cm²) were evaluated under vacuum conditions (˜10⁻⁵ Torr). Over a test period of ˜10⁶ seconds, no degradation of intensity of radiation and current level was detected as shown in FIG. 17F. In some embodiments, the life-time of graphene light emitters can be longer than 4 years. This result attests to the remarkable stability of both the hBN encapsulation and edge contacts even under high electric field, current density, and temperature.

### Example 10: Visible Light Emissions from Graphene Encapsulated in Hexagonal Boron Nitride (hBN) Under Ambient Conditions

This Example demonstrates visible light emissions from graphene encapsulated in hexagonal boron nitride (hBN) under ambient conditions.

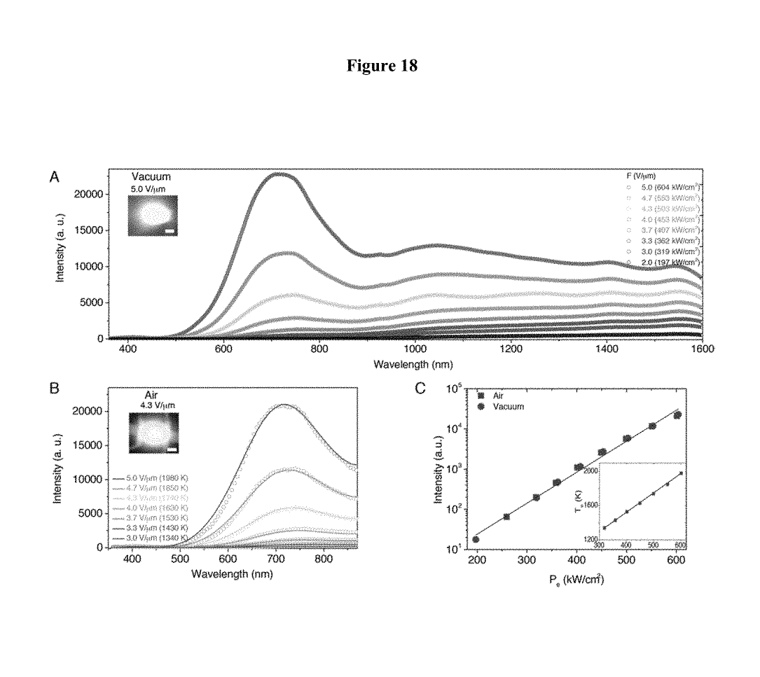

FIG. 18A shows the spectrum of the emitted light with various applied electric field (electric power) under vacuum conditions. The spectrum extends from the visible to near-infrared (400˜1,600 nm), with a single peak at 718 nm with a flat response at near-infrared (>1,000 nm) from several graphene light emitters. The visible light emission and collected radiation spectrum were detected under ambient conditions as shown in FIG. 18B, which shows no noticeable difference to that observed under vacuum conditions. Certain devices showed stable operation in air for a few days before being damaged, while others survived for a few tens of minutes. This can be further evidence of the stability of the hBN encapsulation.

The derived electron temperature (Te) reaches 1,980 K for F=5.0 V/μm. The radiation enhancement due to the hBN layers reaches 460% at the 718 nm peak, relative to graphene greybody thermal radiation. FIG. 18C shows the measured radiation intensity (Pr) of the graphene light emitter as a function of the applied electric power (Pe). Under both vacuum and ambient conditions, Pᵣ∝Pₑ⁴ over a wide range. Te varies linearly Pe as shown in FIG. 18 and the radiation intensity follows Pᵣ ∝Pₑ⁴, as expected from the Stefan-Boltzmann law.

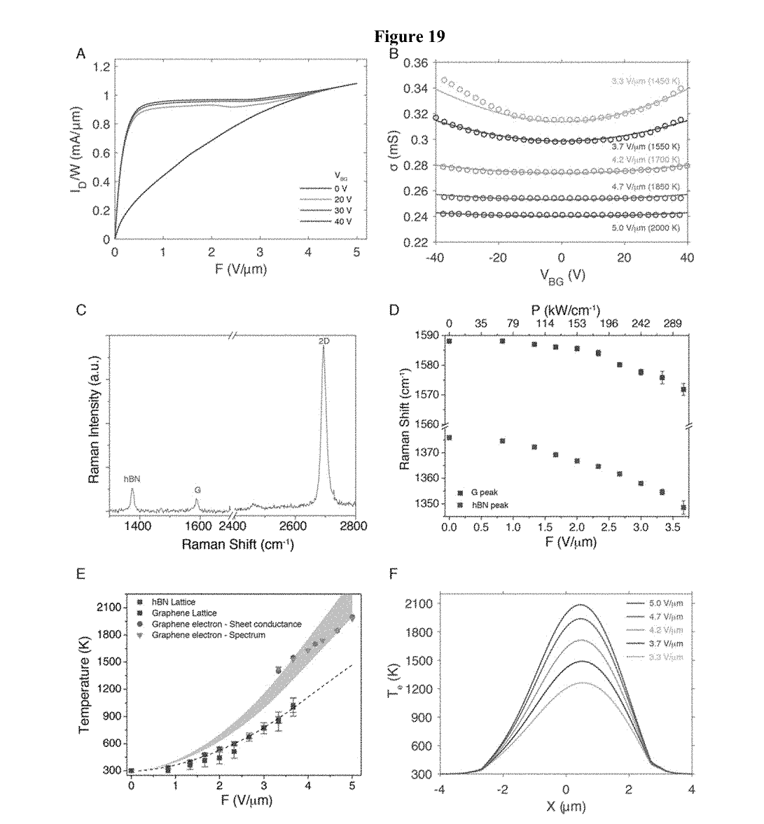

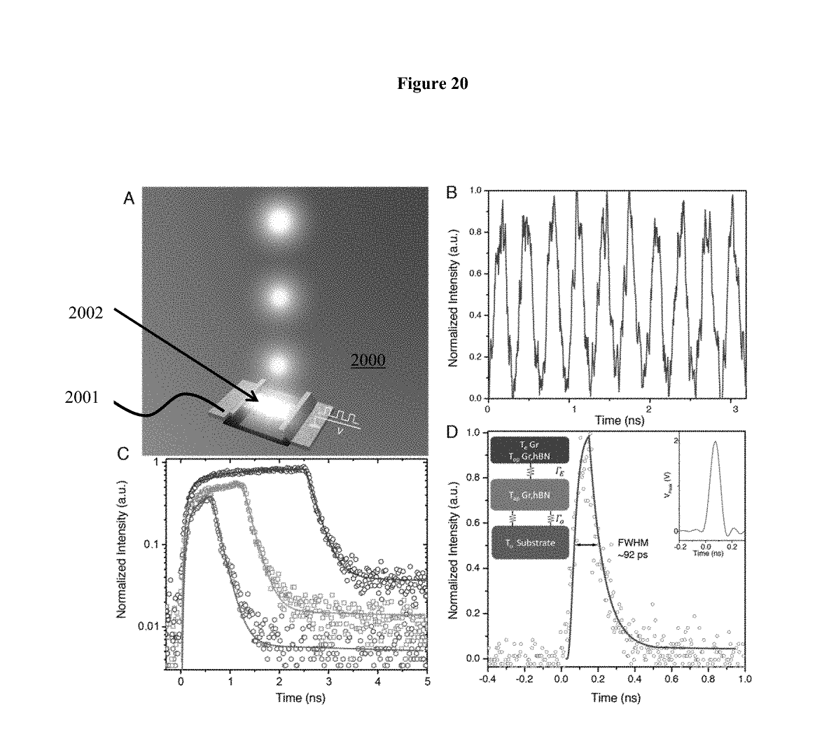

To confirm the decoupling of electron and acoustic phonons in graphene heterostructures, Te was measured by analyzing the emission spectra (FIG. 18B) and the high electric field transport behavior (FIGS. 20A and 20B). The acoustic phonon temperature was measured by Raman spectroscopy (FIGS. 20C and 20D). As shown in FIG. 19A, rapid current saturation was observed under modest electric fields (F>0.5 V/μm) for |V_{BG}|>20V. This can be attributed to efficient backscattering of electrons by emission of optical phonons when the optical phonon activation length LΩ(∝/F, where Ω is the optical phonon energy) becomes smaller than the acoustic phonon scattering length Lₐₚ, which approaches 1 um in hBN-encapsulated graphene at room temperature.

In these heterostructures, graphene electrons can emit optical phonons in the graphene and the hBN, both of which have Ω˜150-200 meV, and LΩ approaches 500 nm at F>0.3-0.4 V/um, resulting in scattering dominated by optical phonon emission and the beginning of current saturation. In SiO2-supported devices, graphene hot electrons can emit SiO2 optical phonons (Ωsio₂˜60-80 meV). Because the saturation current density can be determined by the optical phonon energy, hBN-encapsulated devices achieve nearly twice the current density compared to SiO2-supported devices, allowing the graphene to reach the temperature required for visible light emission. The current modulation by V_{BG} weakens at high bias and becomes negligible for F>4 V/nm. This can be more clearly seen by plotting the sheet conductance (a) as the function of V_{BG} for different values of F (FIG. 19B).

For F<3.3 V/μm, a is modulated by V_{BG}, while above 4 V/μm. The σ is independent of V_{BG}. Under large bias, the electronic carrier density includes both electrostatically induced charge carriers n_{g} ∝V_{BG} and thermally generated charge carriers nₜₕ ∝Tₑ². Since σ∝nₜₒₜeμ, where nₜₒₜ is total carrier density including nₜₕ and n_{g} and e is the electron charge, the gate modulation effect becomes small when nₜₕ>>n_{g}. Using μ∝Te^{-β} for the temperature dependent mobility, where β=2.68 obtained from numerical self-consistent heat transport model, and using Te as an adjustable parameter, numerical calculations of the graphene self-heating can be performed to find good agreement with the measured data (FIG. 19B, solid lines). The derived values of Te are close to those derived from fitting the radiation spectrum (FIG. 18B).

The acoustic phonon temperature (Tₐₚ) of graphene and hBN was measured by Raman spectroscopy (FIGS. 19C and 19D). The graphene G mode and the hBN E_{2g} mode shift downward with temperature due to anharmonic phonon coupling. Tₐₚ of graphene and hBN were measured up to 1,000 K, above which the visible radiation background interfered with the measurement. The measured peak positions are shown in FIG. 19D and the derived temperatures are shown in FIG. 19E.

Tₐₚ of graphene and hBN are nearly equal at high F, and approximately 49% below Te. Thus, Te is out of equilibrium with Tₐₚ due to the energy relaxation bottleneck, which has been seen to follow Tₑ=Tₐₚ+α(Tₐₚ−T₀), where α is a numerical coefficient and T0 is the ambient temperature. Based on the measured Tₑ and Tₐₚ in the graphene-hBN heterostructure, α˜0.45-0.77 was measured as shown in FIG. 19F.

From the measured temperature of the heterostructure (Tₐₚ˜1,250-1,450 K, which corresponds to Te˜2,000 K), the thermal resistance can be calculated based on the Fourier's law for heat transfer ΔTap=RₜₕPₑ, where ΔTap is the lattice (acoustic phonon) temperature difference, Rₜₕ is the vertical total thermal resistance of graphene heterostructure on substrate and Pe is the applied electric power. Rₜₕ˜10,650-11,480 K/W were obtained, which corresponds to a vertical thermal conductance per unit length g=1/(L Rₜₕ)˜14.51-15.65 Wm-1K−1, where L 6 μm. The measured Rₜₕ is dominated by thermal resistance of SiO2 layer (˜8,000-11,000 K/W, for 285 nm thickness) and matches reasonably well with the expected vertical thermal resistance of the heterostructure, including series contributions from the hBN, SiO2, and Si, as well as interfaces between them. In addition, the temperature distribution in hBN encapsulated graphene light emitter was calculated with heat diffusion equation (Formula 7).

$$A \frac{d}{dx} ( {k}_{GBNx} \frac{{dT}_{apx}}{dx} ) + \frac{{dP}_{x}}{dx} - ℊ ( {T}_{apx} - {T}_{a} ) = 0 , \qquad ( 7 )$$

A is the cross-section of graphene and hBN layers. kGBNx is the temperature dependent local thermal conductivity of hBN encapsulated graphene (˜300 Wm-1K−1 at room temperature, ∝Tap^{-0.7}). Tapx is the local lattice temperature. Px is a local power. Based on the above equation and non-equilibrium temperature coefficient α, the Te distribution along the graphene light emitter with various F was calculated as shown in FIG. 3F, which is in qualitative agreement with obtained optical intensity profile of thermal radiation in FIG. 17E.

The non-equilibrium temperature distribution in the graphene presents an opportunity to achieve ultrafast modulation of the thermal light emission. In particular, while thermal relaxation of acoustic phonons in the graphene and hBN requires bulk heat flow through the substrate with a time constant in several tens of nanoseconds, relaxation of the electrons at Tₑ to the acoustic phonon temperature Tap should be substantially faster. Moreover, because the emission intensity varies as Tₑ⁴, cooling to Tₐₚ can result in reduction in emission intensity—approximately 75% for the case shown in FIG. 19E, and even larger for short pulses where Tₐₚ does not reach its steady-state value. To test this conjecture experimentally, a quartz-mounted substrate was used to reduce parasitic capacitance and enable electrical drive at GHz frequencies (FIG. 20A). FIG. 20A provides a schematic illustration of an exemplary system for generating a light emission. In certain embodiments, a system 2000 includes a graphene membrane 2002 and mechanical clamp 2001. When a continuous pulse train at 3 GHz was applied, the radiation intensity was modulated at the same frequency (FIG. 20B), confirming that the non-equilibrium temperature distribution enables a large increase in modulation speed.

To prove the dynamics of this process in more detail, time-resolved thermal radiation measurements were performed using a time-correlated single-photon counting (TCSPC) technique. FIG. 20C shows the response from pulses of 0.8, 1.5, and 2.5 ns width. At the onset of each pulse, a fast-initial rise was detected followed by a more gradual temperature rise, consistent with fast heating of electrons and slower thermalization of the phonon bath. At the end of each pulse, the intensity initially decreases on the sub-ns timescale, with a transition to much slower cooling.

The two regimes each shows roughly linear behavior on the logarithmic scale, indicating simple exponential decay. Moreover, the crossover intensity (and therefore temperature) to slow cooling increases with pulse duration, demonstrating that Tₐₚ reaches its steady-state value only for longer pulse duration, whereas short pulse duration (<300 ps) exhibits the single components of rise and fall of radiation. Furthermore, the generation of light output with 92 ps pulse width, corresponding to 10 GHz bandwidth, was observed under electrical excitation of ˜80 ps pulse width as shown in FIG. 20D. The measured speed of graphene light emitters (10 GHz bandwidth) is not the upper limit of the intrinsic speed of ultrafast graphene light emitter, which were limited by measured setups such as pulse generator, timing jitter of detector, and electrical signal broadening.

The transient cooling of the graphene thermal emitter can be fit by a simple heat transfer model of the strongly coupled electrons-optical phonons bath of graphene and hBN and acoustic phonon bath; and are connected to each other by rate of heat transfer (Γ_{E}) and to the environment by Γ₀ as shown energy relaxation schematic in inset of FIG. 2D. A quantitative fit is to the data (solid lines in FIG. 20C) is provided by assuming that the light intensity varies as T⁴, and taking Γₙ as fitting parameters. Γ₀˜100-125 MWm⁻²K⁻¹ from out-of-plane thermal conductivity of hBN layers (˜20 nm) was obtained. Γ_{E} can be derived from the steady state magnitude of the temperature (as shown in FIG. 19D) rise Te−T0≈P/Γ_{E}, gives Γ_{E}˜3.5−6.0 MWm⁻²K⁻¹ with assumption Γ_{E}<<Γ₀, and which is consistent with theory.

From the fitting of thermal radiation based on this electrical excitation (˜80 ps) as shown in FIG. 21D, the transient heating time constant τₕ˜29 ps and cooling time constant τ_{c}320 ps were calculated. Fast heating is attributed to the extremely small specific heat of electrons in graphene at initial stage of excitation, whereas relative slow cooling is due to the significant contribution of strongly coupled optical phonons specific heat of graphene. Recent studies also suggest that cooling into hBN can be mediated by efficient near-field heat transfer of hot electrons in graphene to the phonon and hybrid polaritonic modes. Thus transient cooling time constant τ_{c}=C_{T}/Γ_{E} is governed by the effective specific heat of electrons-optical phonons of graphene and hBN (C_{T}˜Cₒₚ_{_}_{Gr}+Cₒₚ_{_}_{hBN}). Based on the measured τ_{c}˜320 ps and Γ_{E}˜3.5−6.0 MWm⁻²K⁻¹, C_{T}˜1.12-1.92×10⁻³ Jm⁻²K⁻¹ was obtained.

When graphene optical phonon specific heat is Cₒₚ_{_}_{Gr}˜2.1-6.1×10⁻⁴J Jm⁻² K−1 and effective hBN layers optical phonon specific heat is Cop_hBN=ρtₕₚₚC_{hBN}, where ρ˜2.1×10⁻³>kgm⁻³ is mass density of hBN, tₕₚₚ can be the effective thickness of hBN layers, which are approximately in equilibrium with optical phonon temperature of graphene (FIG. 20D), and C_{hBN}˜8×107 Jkg⁻¹K⁻¹ is an effective hBN optical phonon specific heat. Consistent with the above-mentioned electronic cooling via near field coupling to hybrid plasmon-phonon polaritonic modes, tₕₚₚ˜0.7-1 nm was measured.

The intrinsic speed of graphene light emitter can be limited by the dynamics of charge carrier cooling and approach to the above 100 GHz bandwidth. Optimized device design of graphene light emitters for efficient photon extraction using the optical cavity structure and harnessing tunable electron cooling pathway strategies, such as plasmonics and tunneling structure can allow the realization of the practical ultrafast fast light source.

In addition to the various embodiments depicted and claimed, the disclosed subject matter is also directed to other embodiments having other combinations of the features disclosed and claimed herein. As such, the particular features presented herein can be combined with each other in other manners within the scope of the disclosed subject matter such that the disclosed subject matter includes any suitable combination of the features disclosed herein. The foregoing description of specific embodiments of the disclosed subject matter has been presented for purposes of illustration and description. It is not intended to be exhaustive or to limit the disclosed subject matter to those embodiments disclosed.

It will be apparent to those skilled in the art that various modifications and variations can be made in the methods and systems of the disclosed subject matter without departing from the spirit or scope of the disclosed subject matter. Thus, it is intended that the disclosed subject matter include modifications and variations that are within the scope of the appended claims and their equivalents.

What is claimed is:

1. A method for generating a light emission from graphene, comprising:
a. suspending a graphene membrane using a circular mechanical clamp; and
b. providing a current to the graphene membrane to establish a source-drain bias voltage along the graphene membrane.

2. The method of claim 1, wherein the graphene membrane comprises from about one to about ten layers of carbon atoms.

3. The method of claim 1, wherein the graphene membrane has a width from about 0.5 μm to about 3 μm.

4. The method of claim 1, wherein the graphene membrane is prepared by one of mechanical exfoliation and chemical vapor deposition.

5. The method of claim 1, wherein the source-drain bias voltage is from about 1 V to about 4 V.

6. The method of claim 1, wherein the light emission comprises photons having an energy from about 0.1 eV to about 3 eV.

7. The method of claim 1, wherein the light emission comprises photons having an energy from about 1.2 eV to about 3 eV.

8. The method of claim 1, wherein the graphene membrane is suspended over trench having a trench depth and the method further comprises modulating the trench depth to alter an intensity of the light emission.

9. A method for generating a light emission from graphene, comprising:
a. encapsulating a graphene membrane using a dielectric material; and
b. providing a current to the graphene membrane to establish a source-drain bias voltage along the graphene membrane.

10. The method of claim 9, wherein the dielectric material comprises hexagonal boron nitride (hBN).

11. The method of claim 9, wherein the source-drain bias voltage is from about 6 V to about 45 V.

12. A method for generating a light emission from hBN, comprising:
a. encapsulating a hBN layer using a graphene layer to from a hBN heterostructure; and
b. providing a current to the hBN structure to establish a source-drain bias voltage along the hBN heterostructure.

13. The method of claim 12, wherein the method further comprises performing a direct tunneling injection.

14. The method of claim 12, wherein the hBN heterostructure further comprises a hBN based encapsulating layer.

15. The method of claim 12, wherein the hBN layer comprises an atomically thin tunneling barrier structure.

16. The method of claim 12, wherein the hBN heterostructure comprises a color tunable structure.

17. The method of claim 12, wherein a color of the light emission is tunable between a blue white color to an orange white color.
